(19) United States
(12) Patent Application Publication
(10) Pub. No.: US 2017/0077193 A1
(43) Pub. Date: Mar. 16, 2017

(54) AMOLED DEVICE AND FEBRICATING METHOD THEREOF, AND DISPLAY APPARATUS

(71) Applicants: BOE TECHNOLOGY GROUP CO., LTD., Beijing (CN); ORDOS YUANSHENG OPTOELECTRONICS CO., LTD., Ordos (CN)

(72) Inventors: Baojun LI, Beijing (CN); Fujiang JIN, Beijing (CN)

(21) Appl. No.: 15/155,831

(22) Filed: May 16, 2016

(30) Foreign Application Priority Data
Sep. 10, 2015 (CN) 201510575169.4

(51) Int. Cl. H01L 27/32; H01L 51/00; C09K 11/06; H01L 51/56

(52) U.S. Cl. CPC H01L 27/3244; H01L 51/56; H01L 51/007; H01L 51/0067; H01L 51/0072; H01L 51/0059; H01L 51/006; C09K 11/06

(57) ABSTRACT

The embodiments of the present disclosure relate to an AMOLED device and a fabricating method thereof, and a display apparatus. The AMOLED device comprises: a back plate; a blue hole transport layer on the back plate; an excitation layer on the blue hole transport layer; a blue light emitting layer on the excitation layer; an electron transfer layer on the blue light emitting layer; and a cathode on the electron transfer layer. The excitation layer is excited by a circuit signal of a device to emit ultraviolet light, and the photochromic material is further excited by the ultraviolet light. The blue light emitting layer displays different chromas under different excitation energies. This manner effectively improves the luminous efficiency of the blue light emitting layer, and extends the color gamut to be adaptive to different display environments, thereby improving the display quality.

### CROSS-REFERENCE TO RELATED APPLICATION

This application claims the benefit and priority of Chinese Patent Application No. 201510575169.4, filed Sep. 10, 2015. The entire disclosure of the above application is incorporated herein by reference.

### FIELD

The present disclosure relates to an AMOLED device and a fabricating method thereof, and a display apparatus.

### BACKGROUND

This section provides background information related to the present disclosure which is not necessarily prior art.

The active-matrix organic light emitting diode (AMOLED) is an active light emitting device. As compared with the conventional LCD display mode, the AMOLED display technique requires no backlight lamp and has the self-luminous characteristic. The AMOLED is formed with a very thin organic material film and a glass substrate, and when current passes through, the organic material emits light. Thus the AMOLED display screen can obviously save power, be lighter and thinner, withstand a larger range of temperature change than the LCD display screen, and have a wider visual angle. The AMOLED display technique is promising to become the next generation flat panel display technique following the LCD, and is one of the flat panel display techniques attracting most attentions at present.

FIG. 1 illustrates a structure diagram of an AMOLED device comprising a back plate 1, a blue hole transport layer 2, a blue light emitting layer 3, an electron transfer layer 4, and a metallic cathode 5 from bottom to top, wherein the blue light emitting layer is made of an electrochromic material. However, it is found in the practical use of the AMOLED that the blue light emitting layer (B) has a relatively low luminous efficiency and a narrow color gamut. As illustrated in FIG. 3, the chromaticity coordinate is a fixed value and the entire color gamut is a definite value, thus the luminous quality of the whole AMOLED device is influenced. Thus increasing the luminous efficiency of the blue light emitting layer (B) is vitally important to the life and display of the AMOLED device.

### SUMMARY

This section provides a general summary of the disclosure, and is not a comprehensive disclosure of its full scope or all of its features.

The embodiments described herein provide an AMOLED device and a fabricating method thereof, and a display apparatus. By adding an excitation layer between the blue hole transport layer and the blue light emitting layer of the AMOLED device, the luminous efficiency of the blue material is increased, and the overall efficiency of the AMOLED device is improved, so that the display apparatus formed by the AMOLED device can be better applied in different environments.

In an embodiment described herein, an AMOLED device includes a back plate; a blue hole transport layer on the back plate; an excitation layer on the blue hole transport layer; a blue light emitting layer on the excitation layer; an electron transfer layer on the blue light emitting layer; and a cathode on the electron transfer layer.

In one example, a material forming the excitation layer may be selected from one or more of an azole derivative ultraviolet light-emitting material, an aniline ultraviolet light-emitting material, a biphenyl derivative ultraviolet light-emitting material, and a polysilane ultraviolet light-emitting material.

In one example, the azole derivative ultraviolet light-emitting material is selected from phenylbiphenyl oxadiazole compound (PBD), triazole compound (TAZ), 1, 3, 5-tris (1-phenyl-1H-benzimidazol-2-yl) benzene (TPBI) or dioxazole derivative (OXD-7); the aniline ultraviolet light-emitting material is selected from N, N′-bis (3-methylphenyl)-N, N′-diphenyl-benzidine (TPD) and F₂PA.

In one example, the blue light emitting layer may be formed with a photochromic material.

In one example, the photochromic material may be a colloid material.

In one example, the colloid material may be selected from diarylethene derivative, Schiff base, sulfoxide, osazone, semicarbazone and succinic anhydride.

In one example, the diarylethene derivative may be selected from compounds with the following structures:

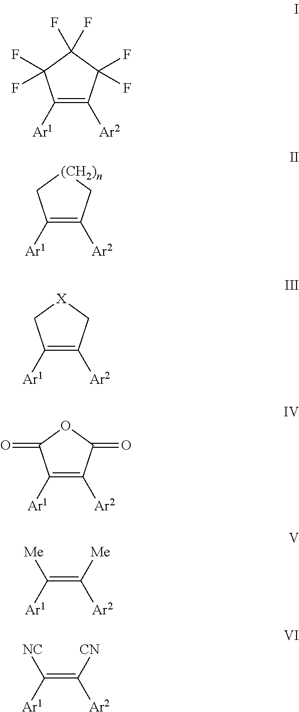

wherein X is S or O;

Ar¹ and Ar² represent heterocyclic aryl;

n is 1 or 2.

In one example, the photochromic material may also be a non-colloid material.

In one example, the non-colloid material may be selected from sodalite doped with halide ion holes, LiNbO₃ doped with Fe or Mo, alumina doped with Bi, TiO₂ carrying Ag nano particles, molybdic acid, hybrid composed of polyacid and small biological molecules, and polyacid containing organic ligands.

In another embodiment described herein, a fabricating method of an AMOLED device comprises: fabricating a back plate; orderly evaporating a blue hole transport layer, an excitation layer, a blue light emitting layer and an electron transfer layer on the back plate; and fabricating a cathode on the electron transfer layer.

In one example, the evaporation process conditions for the excitation layer and the blue light emitting layer may be: a vacuum degree of 5×10⁻⁵ Pa, a layer thickness of 90˜110 μm, a temperature of 300˜400° C., and a magnetic force ≦150 gauss.

In one example, a material forming the excitation layer may be selected from one or more of an azole derivative ultraviolet light-emitting material, an aniline ultraviolet light-emitting material, a biphenyl derivative ultraviolet light-emitting material, and a polysilane ultraviolet light-emitting material.

In one example, the azole derivative ultraviolet light-emitting material may be selected from phenylbiphenyl oxadiazole compound, triazole compound, 1, 3, 5-tris (1-phenyl-1H-benzimidazol-2-yl) benzene and dioxazole derivative; and the aniline ultraviolet light-emitting material may be selected from N, N′-bis (3-methylphenyl)-N, N′-diphenyl-benzidine and F₂PA.

In one example, the blue light emitting layer may be formed with a photochromic material.

In one example, the photochromic material may be a colloid material or a non-colloid material.

In still another embodiment described herein, a display apparatus comprises an AMOLED device, which includes: a back plate; a blue hole transport layer on the back plate; an excitation layer on the blue hole transport layer; a blue light emitting layer on the excitation layer; an electron transfer layer on the blue light emitting layer; and a cathode on the electron transfer layer.

In one example, a material forming the excitation layer may be selected from one or more of an azole derivative ultraviolet light-emitting material, an aniline ultraviolet light-emitting material, a biphenyl derivative ultraviolet light-emitting material, and a polysilane ultraviolet light-emitting material.

In one example, the azole derivative ultraviolet light-emitting material is selected from phenylbiphenyl oxadiazole compound, triazole compound, 1, 3, 5-tris (1-phenyl-1H-benzimidazol-2-yl) benzene and dioxazole derivative; and the aniline ultraviolet light-emitting material is selected from N, N′-bis (3-methylphenyl)-N, N′-diphenyl-benzidine and F₂PA.

In one example, the blue light emitting layer may be formed with a photochromic material.

In one example, the photochromic material may be a colloid material or a non-colloid material.

According to the AMOLED device provided by the embodiment of the present disclosure, by adding an excitation layer between the blue hole transport layer and the blue light emitting layer of the AMOLED device, the luminous efficiency of the blue material is increased, and the overall efficiency of the AMOLED device is improved, so that the display apparatus formed by the AMOLED device can be better applied in different environments.

Further aspects and areas of applicability will become apparent from the description provided herein. It should be understood that various aspects of this disclosure may be implemented individually or in combination with one or more other aspects. It should also be understood that the description and specific examples herein are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a structure diagram of an AMOLED device in the prior art;

FIG. 2 is a structure diagram of an exemplary AMOLED device provided by an embodiment of the present disclosure;

FIG. 3 is a color gamut diagram of an AMOLED device in the prior art;

FIG. 4 is a color gamut diagram of an AMOLED device provided by an embodiment of the present disclosure; and

FIG. 5 is a flow diagram of a fabricating method of an exemplary AMOLED device provided by an embodiment of the present disclosure.

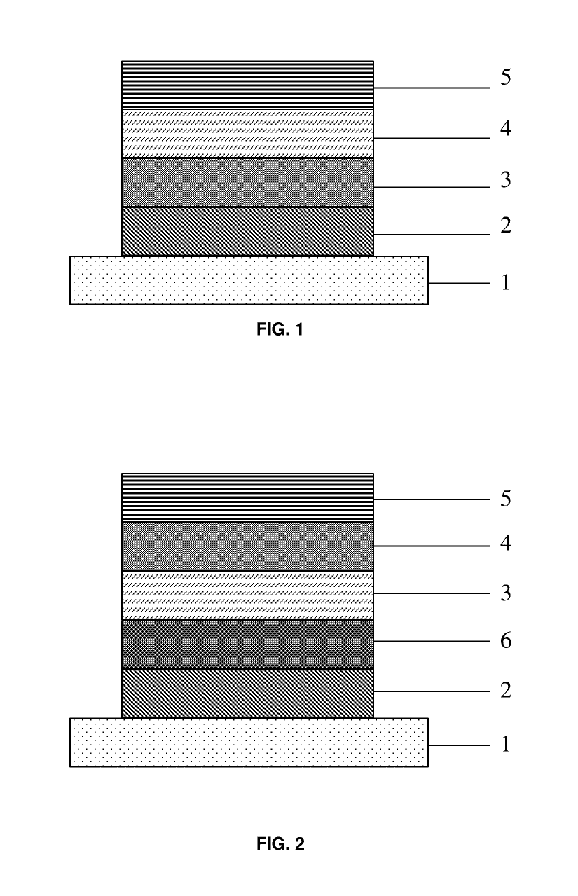

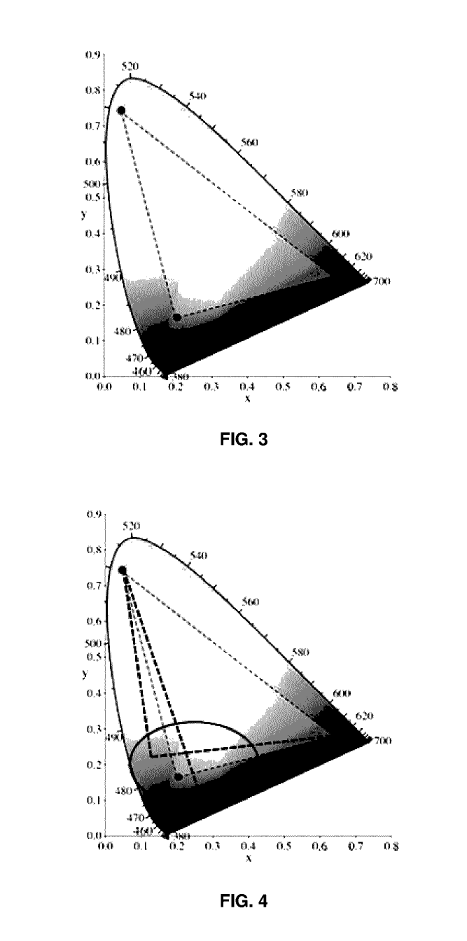

Corresponding reference numerals indicate corresponding parts or features throughout the several views of the drawings.

### DETAILED DESCRIPTION

Example embodiments will now be described more fully with reference to the accompanying drawings.

An embodiment of the present disclosure provides an AMOLED device with a structure as illustrated in FIG. 2, comprising a back plate 1, a blue hole transport layer 2, a blue light emitting layer 3, an electron transfer layer 4 and a metallic cathode 5 from bottom to top, wherein an excitation layer 6 is provided between the blue hole transport layer 2 and the blue light emitting layer 3 to excite the blue light emitting layer with light of different excitation energies, so that the blue light emitting layer displays different chromas.

In the embodiment described herein, the excitation layer 6 may be made of one or more of an azole derivative ultraviolet light-emitting material, an aniline ultraviolet light-emitting material, a biphenyl derivative ultraviolet light-emitting material, or a polysilane ultraviolet light-emitting material.

In one example, the azole derivative ultraviolet light-emitting material may be selected from phenylbiphenyl oxadiazole compound (PBD), triazole compound (TAZ), 1, 3, 5-tris (1-phenyl-1H-benzimidazol-2-yl) benzene (TPBI) or dioxazole derivative (OXD-7). The aniline ultraviolet light-emitting material may be selected from N, N′-bis (3-methylphenyl)-N, N′-diphenyl-benzidine (TPD) and F₂PA.

In which, the structural formula of the PBD is:

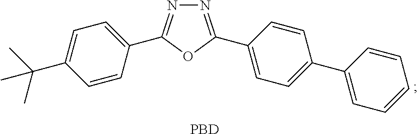 [SMILES: CC(C)(C)c1ccc(-c2nnc(-c3ccc(-c4ccccc4)cc3)o2)cc1 ; "PBD"]

the structural formula of the TAZ is:

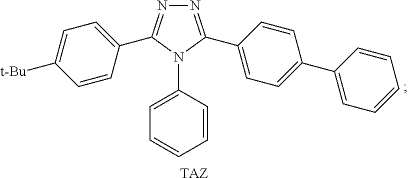

the structural formula of the TPBI is:

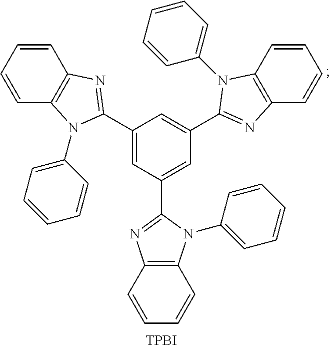

the structural formula of the OXD-7 is:

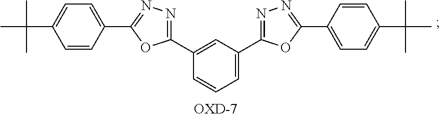 [SMILES: CC(C)(C)c1ccc(-c2nnc(-c3cccc(-c4nnc(-c5ccc(C(C)(C)C)cc5)o4)c3)o2)cc1]

the structural formula of the TPD is:

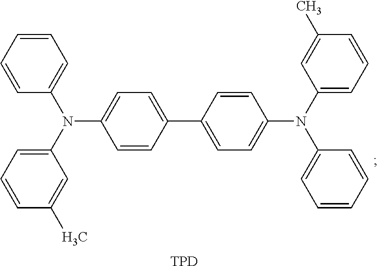 [SMILES: Cc1cccc(N(c2ccccc2)c2ccc(-c3ccc(N(c4ccccc4)c4cccc(C)c4)cc3)cc2)c1 ; "TPD"]

the structural formula of the F₂PA is:

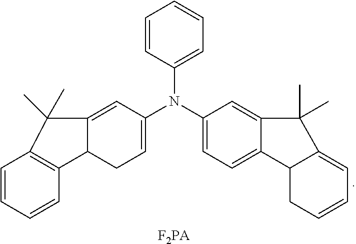

In the AMOLED device provided by the present disclosure, the blue light emitting layer 3 may be made of a photochromic material. In one example, the photochromic material is a colloid material or a non-colloid material. For example, the colloid material is further selected from diarylethene derivative, Schiff base, sulfoxide, osazone, semicarbazone and succinic anhydride.

As a specific implementation of the present disclosure, the diarylethene derivative is selected from compounds with the following structures:

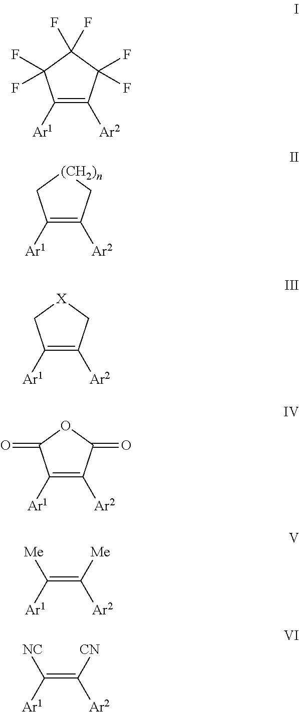

wherein X is S or O;

Ar¹ and Ar² represent heterocyclic aryl;

n is 1 or 2;

Since he characteristic of the compounds of categories I and II is sensitive to green and blue light, the blue light emitting layer made of those compounds may have a better sensitivity.

The diarylethene derivative in the embodiment described herein takes place a thermal irreversible and anti-fatigue photochromic phenomenon in the solution. Either the colored isomer after the light excitation or the colorless isomer before the light excitation can be stably existed for more than 1,000 years under the room temperature. The cyclic process of coloring and fading can be repeated for more than 10,000 times, and the response time is very short (even less than 10 ps). Thereby it haves many advantages such as good photochromism, thermal stability and fatigue resistance, and quick response time.

The photochromic mechanism of the diarylethene derivative in the embodiment described herein is a pericyclic reaction, i.e., under the excitation of ultraviolet light, the compound rotates and closes to generate a colored closed cycle, which can be changed reversely under the irradiation of visible light. The changed color of the diarylethene derivative is stable in the darkness, but after the excitation of visible light, the colored crystals return to the initial colorless state. In which, derivatives of different structures may be changed from colorless to yellow, red, blue or green under the excitation of ultraviolet light. In the present disclosure, the diarylethene derivative is preferably a compound of structural formula I, and by selecting an appropriate excitation light wavelength, a full-color photochromic phenomenon can be displayed to obtain a wider color gamut.

In the AMOLED device provided by the embodiment described herein, the photochromic material may also be selected from the non-colloid material. The non-colloid material may be selected from sodalite doped with halide ion holes, LiNbO₃ doped with Fe or Mo, alumina doped with Bi, TiO₂ carrying Ag nano particles, molybdic acid, hybrid composed of polyacid and small biological molecules, and polyacid containing organic ligands.

In the AMOLED device provided by the embodiment described herein, the blue hole transport layer 2, the electron transfer layer 4 and the metallic cathode 5 all can be made with the conventional materials in the art according to the conventional fabricating methods known by those skilled in the art, which are omitted herein.

According to the AMOLED device in the embodiment described herein, an excitation layer 6 is added between the blue light emitting layer 3 and the blue hole transport layer 2, and the material of the blue light emitting layer 3 is replaced with the photochromic material, thereby obtaining a new type of AMOLED device.

During operations, the excitation layer 6 is excited by a circuit signal on the substrate to emit ultraviolet light, and the photochromic material is further excited by the ultraviolet light. The blue light emitting layer 3 can display different chromas under different excitation energies. This luminous mode effectively improves the luminous efficiency of the blue light emitting layer 3 and extends the color gamut. As illustrated in FIG. 4, the color coordinate varies with the ultraviolet light, and the color gamut is obviously improved to be adaptive to different display environments, thereby improving the display quality.

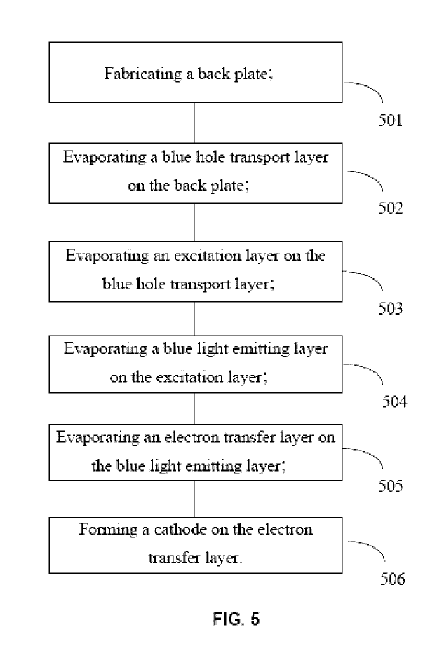

The embodiment of the present disclosure further provides a fabricating method of the AMOLED device, as illustrated in FIG. 5, comprising the steps of: fabricating a back plate (step 501); evaporating a blue hole transport layer on the back plate (step 502); evaporating an excitation layer on the blue hole transport layer (step 503); evaporating a blue light emitting layer on the excitation layer (step 504); evaporating an electron transfer layer on the blue light emitting layer (step 505); and fabricating a metallic cathode on the electron transfer layer (step 506).

In one embodiment, after the blue hole transport layer 2 is evaporated, a MASK for evaporating the excitation layer 6 is fabricated, so as to evaporate the excitation layer 6 with corresponding MASK; next, a MASK for evaporating the blue light emitting layer 3 is fabricated, so as to evaporate the blue light emitting layer 3 with corresponding MASK.

In the above fabricating method, the evaporation process conditions for the excitation layer 6 and the blue light emitting layer 3 may be a vacuum degree of 5×10⁻⁵ Pa, a layer thickness of 90-110 μm, a temperature of 300˜400° C., and a magnetic force ≦150 gauss.
The present disclosure further provides a display apparatus comprising the AMOLED device of any of the above described embodiments or embodiments described herein. The display apparatus may be a cellular phone display screen, a PAD display screen, a TV display screen, etc. using the OLED technique. The display apparatus using the AMOLED device of the present disclosure has the characteristics of higher luminous efficiency and wider color gamut.

### Embodiment 1: an AMOLED Device

An AMOLED device with its structure as illustrated in FIG. 2, comprising a back plate 1, a blue hole transport layer 2, a blue light emitting layer 3, an electron transfer layer 4 and a metallic cathode 5 from bottom to top, wherein an excitation layer 6 is added between the blue hole transport layer 2 and the blue light emitting layer 3.

In one example, the excitation layer 6 is made of a PBD material.

The blue light emitting layer 3 may be formed from a compound with the following structure:

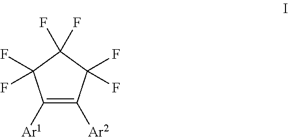

wherein, Ar¹ and Ar² represent heterocyclic aryl.

The blue hole transport layer 2 may be made of a p-type doped layer (m=MTDATA:x% F₄-TCNQ), and the electron transfer layer 4 may be made of a low molecular material of Alq3.

### Embodiment 2: an AMOLED Device

This embodiment provides an AMOLED device, and it differs from Embodiment 1 in that the excitation layer in this embodiment is made of TPBI.

### Embodiment 3: an AMOLED Device

This embodiment provides an AMOLED device, and it differs from Embodiment 1 in that the excitation layer in this embodiment is made of TAZ.

### Embodiment 4: an AMOLED Device

This embodiment provides an AMOLED device, and it differs from Embodiment 1 in that the blue light emitting layer in this embodiment is made of a LiNbO₃ material doped with Fe or Mo.

### Embodiment 5: an AMOLED Device

This embodiment provides an AMOLED device, and it differs from Embodiment 1 in that the blue light emitting layer in this embodiment is made of a TiO₂ material carrying Ag nano particles.

### Embodiment 6: a Fabricating Method of an AMOLED Device

A fabricating method of an AMOLED device, comprising fabricating a back plate, and then orderly evaporating a blue hole transport layer, an excitation layer, a blue light emitting layer and an electron transfer layer, and finally fabricating a metallic cathode.

In one embodiment, after the blue hole transport layer is evaporated, a MASK for evaporating the excitation layer is fabricated, so as to evaporate the excitation layer with corresponding MASK; next, a MASK for evaporating the blue light emitting layer is fabricated, so as to evaporate the blue light emitting layer with corresponding MASK.

The evaporation process conditions for the excitation layer and the blue light emitting layer may be a vacuum degree of 5×10⁻⁵ Pa, a layer thickness of 100 μm, a temperature of 350° C., and a magnetic force 150 gauss.

### Embodiment 7: a Fabricating Method of an AMOLED Device

A fabricating method of an AMOLED device, which is the same as that of embodiment 6 except that, in this embodiment, the layer thickness is 90 μm and the temperature is 300° C. for evaporating the excitation layer and the blue light emitting layer.

### Embodiment 8: a Fabricating Method of an AMOLED Device

A fabricating method of an AMOLED device, which is the same as that of embodiment 6 except that, in this embodiment, the layer thickness is 110 μm and the temperature is 400° C. for evaporating the excitation layer and the blue light emitting layer.

The AMOLED device of any of Embodiments 2 to 5 can be fabricated with the technology described in any of Embodiments 6 to 8.

### Embodiment 9: a Display Apparatus

This embodiment disclosed herein provides a display apparatus, comprising an AMOLED device of any of Embodiments 1 to 5.

The display apparatus using the AMOLED device of the present disclosure has the characteristics of higher luminous efficiency and wider color gamut.

To be pointed out, when the elements and the embodiments of the present disclosure are introduced, the articles “a”, “an”, “the” and “said” are intended to represent the existence of one or more elements.

The expressions “have”, “comprise”, “include” and their grammatic varieties are used in a non-exclusive manner. Thus the expressions “A has B”, “A comprises B” and “A includes B” all indicate a fact that besides B, A further includes one or more additional components and/or constitute elements and a condition that besides B, any other component, constitute element or member is not presented in A.

In addition, the drawings could exaggerate the sizes of the layers and areas for clear illustrations. In addition, it shall be understood that when an element or layer is referred to as being “on” or “above” another element or layer, it may be directly located on other element, or there may be an intermediate layer; when an element or layer is referred to as being “under” or “below” another element or layer, it may be directly located under other element, or there may be one or more intermediate layer or element; and when an element or layer is referred to as being “between” two layers or elements, it may be an unique layer between the two layers or elements, or there may be more than one intermediate layer or element.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

1. An AMOLED device, comprising a back plate;
a blue hole transport layer on the back plate;
an excitation layer on the blue hole transport layer;
a blue light emitting layer on the excitation layer;
an electron transfer layer on the blue light emitting layer; and
a cathode on the electron transfer layer.

2. The AMOLED device according to claim 1, wherein a material forming the excitation layer is selected from one or more of an azole derivative ultraviolet light-emitting material, an aniline ultraviolet light-emitting material, a biphenyl derivative ultraviolet light-emitting material, and a polysilane ultraviolet light-emitting material.

3. The AMOLED device according to claim 2, wherein the azole derivative ultraviolet light-emitting material is selected from phenylbiphenyl oxadiazole compound, triazole compound, 1, 3, 5-tris (1-phenyl-1H-benzimidazol-2-yl) benzene and dioxazole derivative; and
the aniline ultraviolet light-emitting material is selected from N, N′-bis (3-methylphenyl)-N, N′-diphenyl-benzidine, and F₂PA.

4. The AMOLED device according to claim 1, wherein the blue light emitting layer is formed with a photochromic material.

5. The AMOLED device according to claim 4, wherein the photochromic material is a colloid material.

6. The AMOLED device according to claim 5, wherein,
the colloid material is selected from diarylethene derivative, Schiff base, sulfoxide, osazone, semicarbazone and succinic anhydride.

7. The AMOLED device according to claim 6, wherein the diarylethene derivative is selected from compounds with the following structures: 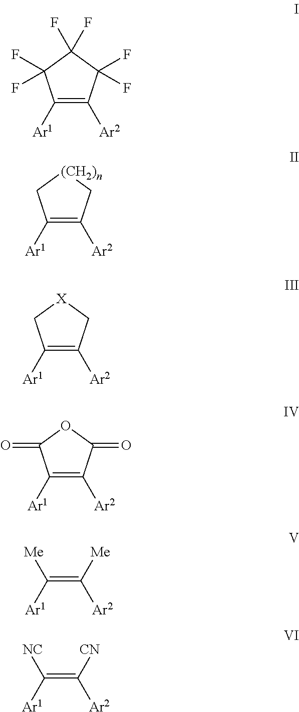
wherein X is S or O;
Ar¹ and Ar² represent heterocyclic aryl;
n=1 or 2.

8. The AMOLED device according to claim 4, wherein the photochromic material is a non-colloid material.

9. The AMOLED device according to claim 8, wherein the non-colloid material is selected from sodalite doped with halide ion holes, LiNbO₃ doped with Fe or Mo, alumina doped with Bi, TiO₂ carrying Ag nano particles, molybdic acid, hybrid composed of polyacid and small biological molecules, and polyacid containing organic ligands.

10. A fabricating method of the AMOLED device according to claim 1, comprising:
fabricating a back plate;
orderly evaporating a blue hole transport layer, an excitation layer, a blue light emitting layer and an electron transfer layer on the back plate; and
fabricating a cathode on the electron transfer layer.

11. The fabricating method according to claim 10, wherein evaporation process conditions for the excitation layer and the blue light emitting layer are: a vacuum degree of 5×10⁻⁵ Pa, a layer thickness of 90˜110 μm, a temperature of 300˜400° C., and a magnetic force ≦150 gauss.

12. The fabricating method according to claim 10, wherein a material forming the excitation layer is selected from one or more of an azole derivative ultraviolet light-emitting material, an aniline ultraviolet light-emitting material, a biphenyl derivative ultraviolet light-emitting material, and a polysilane ultraviolet light-emitting material.

13. The fabricating method according to claim 12, wherein the azole derivative ultraviolet light-emitting material is selected from phenylbiphenyl oxadiazole compound, triazole compound, 1, 3, 5-tris (1-phenyl-1H-benzimidazol-2-yl) benzene and dioxazole derivative; and
the aniline ultraviolet light-emitting material is selected from N, N′-bis (3-methylphenyl)-N, N′-diphenyl-benzidine, and F₂PA.

14. The fabricating method according to claim 10, wherein the blue light emitting layer is formed with a photochromic material.

15. The fabricating method according to claim 14, wherein the photochromic material is a colloid material or a non-colloid material.

16. A display apparatus comprising an AMOLED device, which includes: a back plate;
a blue hole transport layer on the back plate;
an excitation layer on the blue hole transport layer;
a blue light emitting layer on the excitation layer;
an electron transfer layer on the blue light emitting layer; and
a cathode on the electron transfer layer.

17. The display apparatus according to claim 16, wherein a material forming the excitation layer is selected from one or more of an azole derivative ultraviolet light-emitting material, an aniline ultraviolet light-emitting material, a biphenyl derivative ultraviolet light-emitting material, and a polysilane ultraviolet light-emitting material.

18. The display apparatus according to claim 17, wherein the azole derivative ultraviolet light-emitting material is selected from phenylbiphenyl oxadiazole compound, triazole compound, 1, 3, 5-tris (1-phenyl-1H-benzimidazol-2-yl) benzene and dioxazole derivative; and
the aniline ultraviolet light-emitting material is selected from N, N′-bis (3-methylphenyl)-N, N′-diphenyl-benzidine and F₂PA.

19. The display apparatus according to claim 16, wherein the blue light emitting layer is formed with a photochromic material.

20. The display apparatus according to claim 19, wherein the photochromic material is a colloid material or a non-colloid material.
